(19) United States
(12) Patent Application Publication
(10) Pub. No.: US 2026/0018411 A1
(43) Pub. Date: Jan. 15, 2026

(54) REMOTE ICP RADICAL DEPOSITION OF TUNABLE LOW-K DIELECTRIC FILMS

(71) Applicant: Applied Materials, Inc., Santa Clara, CA (US)

(72) Inventors: Jialiang WANG, Santa Clara, CA (US); Kashish SHARMA, Santa Clara, CA (US); Abhijit Basu MALLICK, Fremont, CA (US)

(21) Appl. No.: 18/771,425

(22) Filed: Jul. 12, 2024

(51) Int. Cl. H01L 21/02

(52) U.S. Cl. CPC H10P 14/6336; H10P 14/6682; H10P 14/6686

(57) ABSTRACT

A method for processing a substrate is provided. The method includes disposing a substrate in a processing region of a process chamber and flowing a reaction gas into a remote plasma region of the process chamber, flowing a precursor gas into the processing region through the second plurality of channels in the showerhead, generating an inductively coupled plasma in the remote plasma region using the reaction gas to form plasma radicals, and exposing the precursor gas in the processing region to plasma radicals to form a dielectric film on the substrate with at least 95% step coverage.

### BACKGROUND

### Field

Embodiments of the present disclosure generally relate to processes for forming dielectric layers during fabrication of integrated circuits on semiconductor substrates. More specifically, embodiments described herein relate to processes for forming conformal low-k dielectric films with tunable film properties.

### Description of the Related Art

Current demands for faster circuitry having greater circuit densities has driven to a great degree of current research and innovation into the materials and processes implemented in the fabrication of such integrated circuits. Guided by the current trend of reducing the size of the integrated circuits, it has become necessary to develop materials and fabrication processes that implement low dielectric materials and/or allow for the dielectric constant (k) of such films to be reduced. However, current materials and processes utilized to reduce the dielectric constant of such films often result in poor mechanical properties and performance thereof, or are limited by poor step coverage in which the film quality may strongly depend on the post treatment efficiency. In addition, plasma based process tends to damage the films due to charged particle bombardment and high energy UV irradiation.

Thus, a need remains for the development of dielectric film materials and new fabrication methods to produce conformal low-k dielectric films having improved step coverage and tunable film composition and/or mechanical properties.

### SUMMARY

A method of processing a substrate is provided, according to certain embodiments. The method includes disposing a substrate in a processing region of a process chamber and flowing a reaction gas into a remote plasma region of the process chamber. The remote plasma region is separated from the processing region by a showerhead having a first plurality of channels and a second plurality of channels. The method also includes flowing a precursor gas into the processing region through the second plurality of channels in the showerhead, and generating an inductively coupled plasma in the remote plasma region using the reaction gas to form plasma radicals. The method includes exposing the precursor gas in the processing region to plasma radicals to form a dielectric film on the substrate. The plasma radicals are introduced into the processing region via the first plurality of channels of the showerhead. The dielectric film is formed on the substrate with at least 95% step coverage.

A method of processing a substrate is provided, according to certain embodiments. The method includes disposing a substrate having at least one feature formed thein in a processing region of a process chamber, and flowing a reaction gas into a remote plasma region of the process chamber where the remote plasma region is separated from the processing region by a showerhead having a first plurality of channels and a second plurality of channels. The method also includes flowing a precursor gas into a processing region through the second plurality of channels in the showerhead, generating a plasma in the remote plasma region. The plasma is generated using the reaction gas to form plasma radicals. The method also includes flowing the plasma radical into the processing region through the first plurality of channels in the showerhead, and exposing the precursor gas in the processing region to plasma radicals to form a dielectric film on the substrate and feature thereon. The dielectric film is formed on the substrate and the at least one feature thereon with at least 95% step coverage.

A method of processing a substrate is provided, according to certain embodiments. The method includes disposing a substrate having at least one feature formed thereon in a processing region of a process chamber. The at least one feature formed on the substrate includes an aspect ratio ranging between about 1:1 and about 50:1. The method also includes flowing a reaction gas into a remote plasma region of the process chamber, flowing a precursor gas into a processing region of the process chamber, generating a plasma in the remote plasma region using the reaction gas to form plasma radicals, flowing plasma radicals into the processing region, and exposing the precursor gas in the processing region to plasma radicals to form a conformal dielectric film on the substrate. The conformal dielectric film is formed on the substrate with at least 95% step coverage over the at least one feature and the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 is a schematic cross-sectional view of a process chamber that may be used to perform the methods described herein, according to certain embodiments;

FIG. 2 is a flow chart depicting an exemplary method of forming a low-k dielectric film using the process chamber illustrated in FIG. 1, according to certain embodiments;

FIG. 3 is a graph illustrating an example of tuning the structural properties or bonding configurations of a deposited dielectric film by varying the processing temperature, according to certain embodiments; and

FIG. 4 is a graph illustrating an example of tuning the chemical composition of deposited dielectric films by varying the processing conditions, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure provides techniques for radical based deposition of low-k dielectric films. In various embodiments, the present disclosure provides for conformal deposition of dielectric films with tunable film composition and properties. In other embodiments, the present disclosure provides for conformal deposition of dielectric films on substrate features with improved step coverage. Certain details are set forth in the following description and figures to provide a thorough understanding of various implementations of the disclosure. Other details describing well-known methods and systems often associated with the deposition of thin films are not set forth in the following disclosure to avoid unnecessarily obscuring the description of the various implementations.

Many of the details, components and other features described herein are merely illustrative of particular implementations. Accordingly, other implementations can have other details, components, and features without departing from the spirit or scope of the present disclosure. In addition, further implementations of the disclosure can be practiced without several of the details described below.

Other deposition chambers may also benefit from the present disclosure and the parameters disclosed herein may vary according to the particular deposition chamber used to form the dielectric film described herein. For example, other deposition chambers may have a larger or smaller volume, requiring gas flow rates that are larger or smaller than those recited for deposition chambers available from Applied Materials, Inc.

Embodiments of the present disclosure provide for deposition of low-k dielectric films, such as low-k SiOC films on substrates. While conventional processes may deposit films of similar materials, the films may suffer from poor conformality or step coverage, or the dielectric constant of deposited film may not be low enough to reduce RC delay and improve interconnect performance. In various embodiments, the present disclosure utilizes a radical based chemical vapor deposition process driven by a remote plasma source for forming conformal dielectric films on substrate with improved step coverage. Radical based CVD typically have the advantages of well controlled growth conditions, low thermal budget, free of defect and high quality films. In some embodiments, which may be combined with other embodiments, the radical based deposition process described herein utilizes low energy plasma radicals generated by the remote plasma source for reacting with a precursor gas to deposit the dielectric film on the substrate. Due to the low energy of the plasma radicals cracking and reacting with the precursor gas, it was observed that desired bonds of the deposited film can be preserved by modifying the processing parameters (e.g., temperature, pressure, RF power, flow rate) so as to tune the chemical composition and/or properties of the deposited dielectric film. Accordingly, methods of the present disclosure also provide for forming low-k dielectric films with tunable film composition and properties. In contrast to conventional PECVD processes in which the deposition species are provided directly to the substrate by a generated plasma, the plasma radicals introduced to the substrate according to the present disclosure are neutral species are not directional and are able to diffuse and react with precursors in deep and narrow features (e.g., trenches, gaps, vias) on the substrate more readily. Accordingly, the aforementioned advantages provide for dielectric films with greater conformality and improved step coverage (e.g., > 95%).

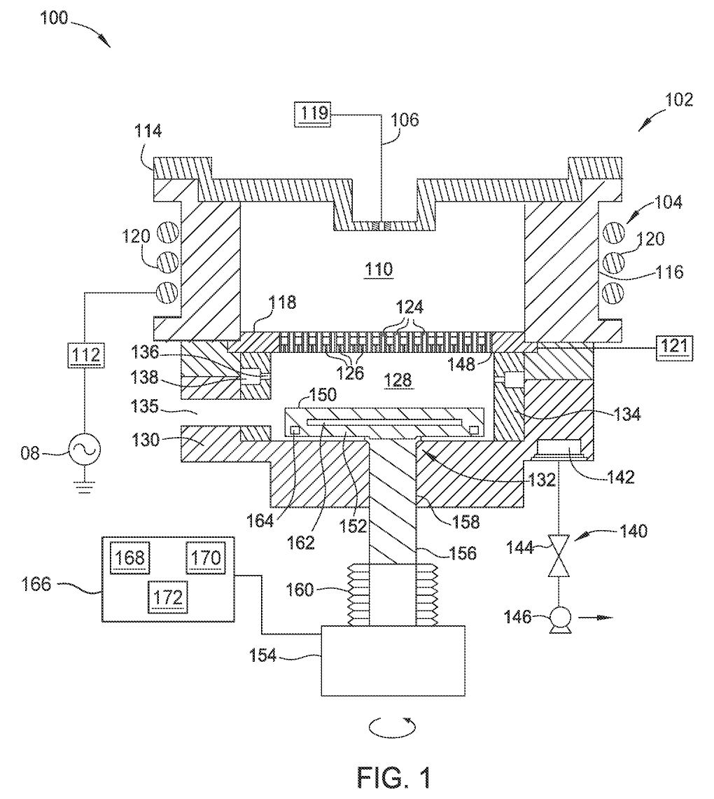

FIG. 1 is a cross-sectional view of a process chamber 100 for performing methods of the present disclosure, according to certain embodiments. In an embodiment, the process chamber 100 may be used for performing method 200 described below for forming a low-k SiOC film on a substrate.

In an embodiment, the process chamber 100 includes a lid assembly 102 having a remote radical source. In certain embodiments, the remote radical source may be any suitable source that is capable of generating radicals. The remote radical source may be a remote plasma source, such as a radio frequency (RF) or very high radio frequency (VHRF) capacitively coupled plasma (CCP) source, an inductively coupled plasma (ICP) source, a microwave induced (MW) plasma source, a DC glow discharge source, an electron cyclotron resonance (ECR) chamber, or a high density plasma (HDP) chamber. Alternatively, the remote radical source may be an ultraviolet (UV) source or the filament of a hot wire chemical vapor deposition (HW-CVD) chamber.

As shown in FIG. 1, the remote radicle source comprises an inductively coupled plasma apparatus 104 disposed about the process chamber 100. The inductively coupled plasma apparatus includes an RF feed structure for coupling an RF power supply 108 to one or more RF coils, e.g., RF coil 120. The RF power supply 108 is coupled to the RF feed structure via a match network 112. The RF coil 120 is coaxially disposed about a remote plasma region 110 of the process chamber 100 and is configured to inductively couple RF power into the process chamber 100 to form a plasma in the remote plasma region 110. The relative position, diameter of the coil, and/or the number of turns in the RF coils can each be adjusted as desired to control, for example, the profile or density of the plasma being formed via controlling the inductance on each coil 120.

The RF power source 108 can provide RF power at a frequency and power as appropriate for a particular application based on the material of the dielectric film being deposited and the desired chemical composition and bond structures of the film. For example, the RF power source 108 may illustratively be capable of producing up to about 6000 W (but not limited to about 6000 W) at a fixed or tunable frequency in a range from about 50 kHz to about 62 MHz, such about 13.56 MHz, although other frequencies and powers may be provided as desired for particular applications. When RF current is fed to the RF coils 120 via the RF feed structure from the RF power supply 108, an inductively coupled plasma can be formed inside the remote plasma region 110 of the chamber 100 from an electric field generated by the RF coils 120.

The inductively coupled plasma may be generated from a reaction gas flowed to the remote plasma region 110 from one or more gas source 119. When receiving power from the RF power source 108, the ICP apparatus 104 forms an electric field that energizes the reaction gases provided to the remote plasma region 110 of the process chamber 100 to form the plasma. One or more reaction gases, which may be radical-forming gases, may enter the remote plasma region 110 via the one or more gas inlets 106. For example, the one or more gas inlets 106 may be coupled at a second end to an upstream gas source 119 of process gases that may be used to generate radicals in the remote plasma region 110 of the process chamber 100. The one or more process gases for generating the radicals may comprise a hydrogen containing gas, such as hydrogen (H₂) or ammonia (NH₃). Depending on the material of the dielectric film desired to be formed and the radicals needed, other radical-forming gases such as Ar, He, or N2 may alternatively be used.

The top plate 114 is part of the lid assembly 102, which also includes a lid rim 116 and a dual-channel shower head 118. The top plate 114, lid rim 116, and the dual-channel showerhead 118 define the remote plasma region 110. Showerhead 118 therefore allows a plasma generated in the remote plasma region 110 to avoid directly exciting gases in a processing region 128 of the process chamber 100, while still allowing radicals from the generated plasma to flow through from the remote plasma region 110 into the processing region 128.

Optionally, the remote plasma region 110 may include a liner (not shown). The liner may cover surfaces of the top plate 114 and the lid rim 116 that are within the remote plasma region 110. The liner 122 may comprise a material that is substantially unreactive to radicals. For example, the liner 122 may comprise AlN, SiO₂, Y₂O₃, MgO, anodized Al₂O₃, sapphire, ceramics containing one or more of Al₂O₃, sapphire, AlN, Y₂O₃, MgO, or plastics. Alternatively or in addition to, the surfaces of the remote plasma region 110 that are in contact with radicals may be composed of or coated with a material that is substantially unreactive to radicals. For example, the surfaces may be composed of or coated with AlN, SiO₂, Y₂O₃, MgO, anodized Al₂O₃, sapphire, ceramics containing one or more of Al₂O₃, sapphire, AlN, Y₂O₃, MgO, or plastics. If a coating is used, the thickness of the coating may be between about 1 μm and about 1 mm. By not consuming the generated radicals, the radical flux to a substrate disposed in the process chamber 100 may increase.

Gases (e.g., process and other gases) and/or plasma effluents (e.g., ions and radicals) that enter the processing region 128 of the process chamber 100 may pass through the showerhead 118 and into the processing region 128. In an embodiment, which can be combined with other embodiments, radicals and neutral species from the inductively coupled plasma generated in the remote plasma region 110 may pass through a first plurality of channels 124 extending through the showerhead 118 to enter the processing region 128. The showerhead 118 further includes a second plurality of channels 126 that is smaller in diameter than the first plurality of channels 124. The second plurality of channels 126 connects to an internal volume (not shown) of the showerhead 118 and is not in fluid communication with the first plurality of channels 124. In an embodiment, one or more gas source 121 may be coupled to the dual-channel showerhead 118 in fluid communication with inner volume of the showerhead 118 and the second plurality of channels 126. The gas source 121 may provide a precursor gas, such as a silicon containing gas, to the dual-channel showerhead 118. The precursor gas from the gas source 121 may flow through inner volume of the dual-channel showerhead 118 to the processing region 128 via the second plurality of channels 126.

Since the first plurality of channels 124 is not in fluid communication with the internal volume of the showerhead 118, the radicals passing through the first plurality of channels 124 from the remote plasma region 110 are not exposed to the precursor gas flowing through the second plurality of channels 126 when flowing through the dual-channel showerhead 118. Because the showerhead 118 contains two channels that are not in fluid communication of each other, the showerhead 118 is a dual-channel showerhead 118. In certain embodiments, each of the first plurality of channels 124 has an inner diameter of about 0.10 to about 0.35 in. In certain embodiments, which can be combined with other embodiments, each of the second plurality of channels 126 has an inner diameter of about 0.01 in to about 0.04 in. In some embodiments, the dual-channel showerhead 118 may be heated or cooled. In one embodiment, which can be combined with other embodiments, the dual-channel showerhead 118 is heated to a temperature of about 100°C to about 250°C during processing. In another embodiment, which can be combined with other embodiments, the dual-channel showerhead 118 is cooled to a temperature of about 25°C to about 75°C.

The first plurality of channels 124 are configured to suppress the migration of ionically-charged species out of the remote plasma region 110 while allowing uncharged neutral species or radicals to pass through the showerhead 118 into the processing region 128. For example, the aspect ratio of the channels 124 (i.e., the inner diameter to length) and/or the geometry of the channels 124 may be controlled so that the flow of ionically-charged species in the activated gas passing through showerhead 118 is reduced. In another example, the first plurality of channels 124 in showerhead 118 may include a tapered portion that faces the remote plasma region 110, and a cylindrical portion that faces the processing region 128. The cylindrical portion may be proportioned and dimensioned to control the flow of ionic species passing into the processing region 128. In another embodiment, which may be combined with other embodiments described herein, an adjustable electrical bias may also be applied to showerhead 118 as an additional means to control the flow of ionic species through showerhead 18. In some embodiments, which can be combined with other embodiments, the uncharged species and radicals may include highly reactive species that are transported with less-reactive carrier gas through the first plurality of channels 124. It is contemplated that in some examples the uncharged species and radicals may flow through the first plurality of channels 124 without a carrier gas.

As noted above, the first plurality of channels 124 is configured to reduce the flow of ionic species from the generated plasma through the showerhead 118, and in some instances completely suppress any such flow so that only the uncharged species and/or radicals from the plasma generated in the remote plasma region 110 enter the process region 128. Controlling the amount of ionic species passing through showerhead 118 provides increased control over the gas mixture brought into contact with the substrate disposed in the processing region 128, which in turn increases control of the deposition characteristics of the processing gas mixture in the processing region 128. For example, limiting the makeup of the processing gas mixture in the processing region 128 to low energy radicals provides for preserving desired bonds and structures of the precursors in the deposited film, which in turn allows for tuning certain electrical and/or mechanical properties of the film. For example, tuning processing parameters during deposition to tune the composition (e.g., carbon %) of the SiOC film being deposited in turn provides for tuning the dielectric constant or k-value of the film.

The process chamber 100 may include the lid assembly 102, a chamber body 130, and a support assembly 132. The support assembly 132 may be at least partially disposed within the chamber body 130. The chamber body 130 may include a slit valve opening 135 to provide access to the interior of the process chamber 100. The chamber body 130 may include a liner 134 that covers the interior surfaces of the chamber body 130. The liner 134 may include one or more apertures 136 and a pumping channel 138 formed therein that is in fluid communication with a vacuum system 140. The apertures 136 provide a flow path for gases into the pumping channel 138, which provides an egress for the gases within the process chamber 100. Alternatively, the apertures and the pumping channel may be disposed in the bottom of the chamber body 130, and the gases may be pumped out of the process chamber 100 from the bottom of the chamber body 130.

The vacuum system 140 may include a vacuum port 142, a valve 144 and a vacuum pump 146. The vacuum pump 146 is in fluid communication with the pumping channel 138 via the vacuum port 142. The apertures 136 allow the pumping channel 138 to be in fluid communication with the processing region 128 within the chamber body 130. The processing region 128 is defined by a lower surface 148 of the dual-channel showerhead 118 and an upper surface 150 of the support assembly 132, and the processing region 128 is surrounded by the liner 134.

The support assembly 132 may include a support member 152 to support a substrate (not shown) for processing within the chamber body 130. The substrate may be any standard wafer size, such as, for example, 300 mm. Alternatively, the substrate may be larger than 300 mm, such as 450 mm or larger. The support member 152 may comprise AlN or aluminum depending on operating temperature. The support member 152 may be configured to chuck the substrate and the support member 152 may be an electrostatic chuck or a vacuum chuck.

The support member 152 may be coupled to a lift mechanism 154 through a shaft 156 which extends through a centrally-located opening 158 formed in a bottom surface of the chamber body 130. The lift mechanism 154 may be flexibly sealed to the chamber body 130 by bellows 160 that prevents vacuum leakage from around the shaft 156. The lift mechanism 154 allows the support member 152 to be moved vertically within the chamber body 130 between a process position and a lower, transfer position. The transfer position is slightly below the opening of the slit valve 135. During operation, the spacing between the substrate and the dual-channel showerhead 118 may be minimized in order to maximize radical flux at the substrate surface. For example, the spacing may be between about 100 mils and about 5,000 mils; however, other spacings are also contemplated. The lift mechanism 154 may be capable of rotating the shaft 156, which in turn rotates the support member 152, causing the substrate disposed on the support member 152 to be rotated during operation. Rotation of the substrate helps improving deposition uniformity.

One or more heating elements 162 and a cooling channel 164 may be embedded in the support member 152. The heating elements 162 and cooling channel 164 may be used to control the temperature of the substrate during operation. The heating elements 162 may be any suitable heating elements, such as one or more resistive heating elements. The heating elements 162 may be connected to one or more power sources (not shown). The heating elements 162 may be controlled individually to have independent heating and/or cooling control on multi-zone heating or cooling. With the ability to have independent control on multi-zone heating and cooling, the substrate temperature profile can be enhanced at any giving process conditions. A coolant may flow through the channel 164 to cool the substrate. The support member 152 may further include gas passages extending to the upper surface 150 for flowing a cooling gas to the backside of the substrate.

The function of the process chamber 100 can be controlled by a computing device 166. The computing device 166 may be one of any form of general purpose computer that can be used in an industrial setting for controlling various chambers and sub-processors. The computing device 166 includes a computer processor 168. The computing device 166 includes memory 170. The memory 170 may include any suitable memory, such as random access memory, read only memory, flash memory, hard disk, or any other form of digital storage, local or remote. The computing device 166 may include various support circuits 172, which may be coupled to the computer processor 168 for conventionally supporting the computer processor 168. Software routines, as required, may be stored in the memory or executed by a second computing device (not shown) that is remotely located.

The computing device 166 may further include one or more computer readable media (not shown). Computer readable media generally includes any device, located either locally or remotely, which is capable of storing information that is retrievable by a computing device. Examples of computer readable media useable with embodiments of the present embodiments include solid state memory, floppy disks, internal or external hard drives, and optical memory (CDs, DVDs, BR-D, etc.). In one embodiment, the memory 170 may be the computer readable media. Software routines may be stored on the computer readable media to be executed by the computing device.

The software routines, when executed, transform the general purpose computer into a specific process computer that controls the chamber operation so that a chamber process is performed. Alternatively, the software routines may be performed in hardware as an application specific integrated circuit or other type of hardware implementation, or a combination of software and hardware.

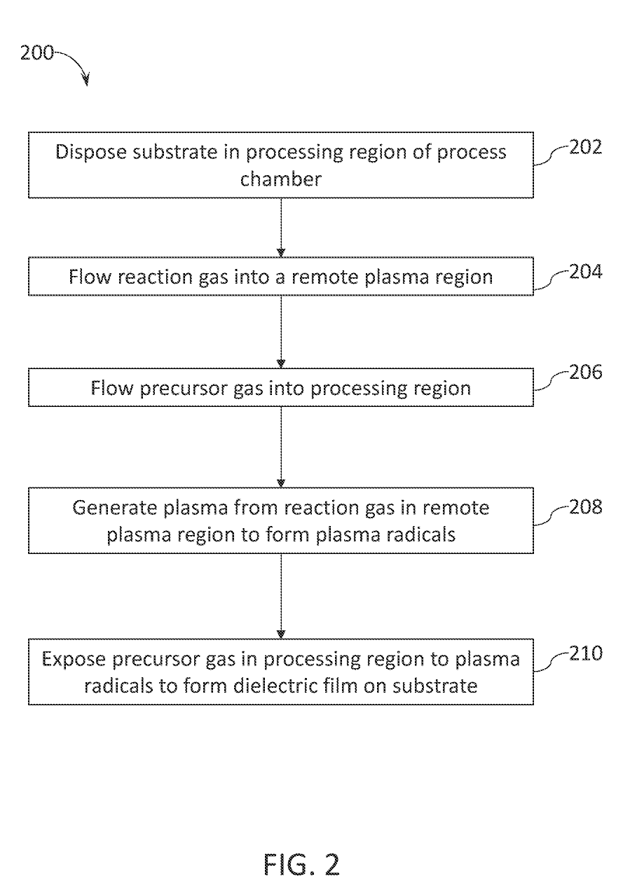

FIG. 2 depicts a flow diagram showing selected operations of a method 200 for depositing low-k dielectric films onto a substrate, according to certain embodiments. At operation 202, a substrate may be introduced to a process chamber (e.g., process chamber 100) and positioned on a substrate support disposed in a processing region of the process chamber capable of performing a chemical vapor deposition process.

At operation 204, at least one reaction gas is flowed into a remote plasma region of the process chamber. The reaction gas may be radical-forming gas for use in generating radicals. In an embodiment, depending on the material of the dielectric film desired to be formed, the reaction gas may comprise a hydrogen containing gas, such as hydrogen (H₂) or ammonia (NH₃), other radical-forming gases such as Ar, He, N₂, O₂ and mixtures thereof.

For example, the radical-forming reaction gas may be a mixture of H₂ and N₂. Alternatively, the radical-forming reaction gas may be a mixture of H₂ and O₂. In another embodiment, the radical-forming gas may be a mixture of H₂, N₂, and O₂. In various alternative embodiments, the mixture of radical-forming gases may comprise NH₃ and H₂. The radicals may include hydrogen radicals, hydroxyl radicals, nitrogen radicals, NH radicals, oxygen radicals, and mixtures thereof. Hydrogen radicals can be generated from H₂, a mixture of H₂ and NH₃, a mixture of H₂ and O₂, and/or a mixture of H₂ and N₂. Hydroxyl radicals can be generated from a mixture of O₂ and H₂. Nitrogen radicals can be generated from a mixture of H₂ and N₂. Nitrogen and NH radicals may be generated from NH₃ and/or a mixture of NH₃ and H₂. Oxygen radicals can be generated from O₂ and/or a mixture of H₂ and O₂.

In certain embodiments, which can be combined with other embodiments, the reaction gas in operation 204 for forming the radicals may be flowed into the remote plasma region of the process chamber at a flow rate between about 1 sccm and about 5000 sccm, such as between about 50 sccm and about 2500 sccm, between about 100 sccm and about 5000 sccm, between about 100 sccm and about 3000 sccm, between about 100 sccm and about 2000 sccm, or between about 100 sccm and about 4000 sccm. If used, the flow rate of carrier gases (e.g., argon or helium) may range from about 1 sccm to about 10,000 sccm.

In operation 206, at least one precursor gas is flowed into a processing region of the process chamber separate from the remote plasma region for generating a plasma. The precursor gas used may be selected based on the material of the dielectric film desired to be deposited on the substrate. In an embodiment, the precursor gas may include one or more hydrocarbon gases, such as CH₄, C₂H₂, and C₃H₆. In another embodiment, which can be combined with other embodiments, the precursor gas may include one or more silicon-containing gases. For example, the one or more precursor gases may include silane (SiH₄), disilane (Si₂H₆), or tetraalkyl orthosilicate gases (TEOS). Tetraalkyl orthosilicate gases include gases consisting of four alkyl groups attached to a SiO₄⁴⁻ ion. More particularly, the one or more precursor gases may be (dimethylsilyl) (trimethylsilyl) methane ((Me)₃SiCH₂SiH(Me)₂); hexamethyldisilane ((Me)₃SiSi(Me)₃); trimethylsilane ((Me)₃SiH); tetramethylsilane ((Me)₄Si); tetraethoxysilane ((EtO)₄Si); tetramethoxysilane ((MeO)₄Si); tetrakis-(trimethylsilyl)silane ((Me₃Si)₄Si); (dimethylamino) dimethylsilane ((Me₂N)SiHMe₂); dimethyldiethoxysilane ((EtO)₂Si(Me)₂); dimethyldimethoxysilane ((MeO)₂Si(Me)₂); methyltrimethoxysilane ((MeO)₃Si(Me)); dimethoxytetramethyl-disiloxane (((Me)₂Si(OMe))₂O); tris(dimethylamino)silane ((Me₂N)₃SiH); bis(dimethylamino)methylsilane ((Me₂N)₂CH₃SiH); disiloxane ((SiH₃)₂O); and combinations thereof.

The precursor gas may be flowed into the processing region at a flow rate ranging from about 5 sccm to about 1000 sccm, such as between about 10 sccm and about 500 sccm. For example, a hydrocarbon precursor gas may be flowed at a flow rate ranging from about 10 sccm to about 1000 sccm. In another example, a silicon-containing precursor gas may be flowed at a flow rate ranging from about 10 sccm to about 500 sccm.

The temperature of process chamber 100 may be maintained between about 150°C and about 600°C, such as between about 200°C and about 550°C, or between about 200°C and about 350°C. The pressure of the process chamber 100 may be maintained between about .1 Torr and about 15 Torr, such as between about 0.2 Torr and about 5 Torr, between about .2 Torr and about 8 Torr, between about .2 Torr and about 10 Torr, between about 5 Torr and about 12 Torr, between about 5 Torr and about 10 Torr, or between about 3 Torr and about 8 Torr.

In operation 208, a remote inductively coupled plasma is generated in the remote plasma region of the process chamber from the reaction gas flowed in operation 204 to form plasma effluents such as ions, radicals, neutral species. In an embodiment, operation 208 may comprise forming at least one of hydrogen radicals, nitrogen radicals, NO radicals, NH radicals, hydroxyl radicals, argon radicals, helium radicals, and oxygen radicals from the reaction gas in operation 204. As the remote plasma region in process chamber 100 is separated from the processing region by a dual-channel showerhead, the generated plasma in the remote plasma region does not directly react with and excite the precursor gases in the processing region of the process chamber 100. In an embodiment, the reaction gas in the remote plasma region may be ignited into a plasma by applying RF power to the RF coils. In an embodiment, the RF power applied may be between about 200 Watts and about 6000 Watts, such as between about 500 Watts and about 2000 Watts, between about 2000 Watts and about 5000 Watts, or between about 200 Watts and about 2000 Watts. The RF Power may be provided at a fixed or tunable frequency in a range from about 50 kHz to about 62 MHz, although other frequencies and powers may be provided as desired for particular applications.

In operation 210, the substrate and the precursor gas in the processing region of the process chamber 100 are exposed to the radicals generated in the remote plasma region in operation 208. As discussed above, the dual-channel showerhead of process chamber 100 is configured to control the passage of the plasma effluents through the showerhead. In an embodiment, the showerhead is configured so that the flow of ions is reduced or suppressed such that only radicals and/or neutral species are introduced into the processing region in operation 210. In an exemplary embodiments, the radicals in the remote plasma region of process chamber 100 flow into the processing region through a first plurality of channels in the dual-channel showerhead. The radicals in the processing region then react with the precursor gas in the processing region to deposit a dielectric film on the substrate.

In an embodiment, which can be combined with other embodiments, radicals in operation 210 are supplied to the processing region until a dielectric film of a desired thickness is formed on the substrate. In some embodiments, the reaction gas for forming the radicals is supplied to the remote plasma region and precursor gas to the processing region until the dielectric film deposited is formed with the desired thickness. The dielectric film formed comprises one or more of a low-k SiOC dielectric film, Si, SiN, SiO, SiOCN, SiON, Carbon, SiC, BN, or BCN. The resulting dielectric films are deposited on the substrate to a thickness between about 1 nm and about 50 nm, although other thicknesses are contemplated.

Advantages of the present disclosure using radicals and/or other neutral species to deposit the dielectric film can reduce plasma damage compared to conventional PECVD processes that include ion bombardment of growing films. Moreover, dielectric films deposited according to the methods disclosed herein offer greater conformality than conventional PECVD techniques. Although not to be limited by theory, it is believed that the improved conformality is related to the inability of plasma, which is limited by the thickness of the plasma sheath, to extend to the bottom of very deep trenches. On the other hand, radicals can diffuse into and react with precursors in deep features of substrate much more readily thereby providing for improved step coverage on such features. The methods disclosed herein demonstrated improved step coverage of at least about 95% on vertical and lateral features of substrates of varying size and dimensions. For example, in some embodiments, films were form with improved step coverage of at least about 95% on vertical or lateral features having a critical dimension between about 20 nm and about 2000 nm, and aspect ratios ranging between about 1:1 and about 50:1.

While FIG. 2 illustrates one example of a flow diagram, it is to be noted that variations of method 200 are contemplated. For example, it is contemplated that operation 206 may occur prior to operation 204. Additionally, it is contemplated that one or more of operations 204-210 may occur concurrently.

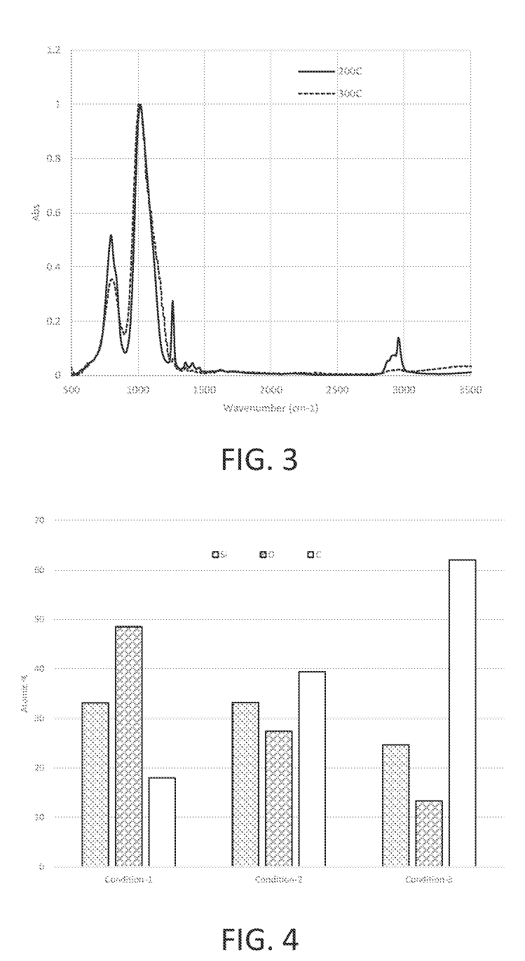

FIG. 3 is a graph illustrating the IR spectrum of SiOC dielectric films formed using the methods disclosed herein at different processing temperatures. Due to the low energy of the plasma radicals cracking and reacting with the precursor gas to form the dielectric film, it was observed that desired bonds and chemical structures of the deposited film could be preserved by modifying one or more processing parameters. As shown in FIG. 3, modification of processing temperature provided for tuning the structural properties or bonding configurations of the deposited film, such as the tuning of C-O, Si-CH₃, Si-C-Si, and/or C-H bonds in the resulting deposited film. Accordingly, during deposition of the dielectric film, parameters such as process temperature, process pressure, RF power, and flow rate of processes gases (reaction and precursor gases) are adjusted to tune the chemical composition and properties of the dielectric film.

FIG. 4 is a graph showing the atomic % of Si, O, and C of SiOC dielectric films formed using the methods disclosed herein under different processing conditions. In certain embodiments, the chemical composition of the resulting film, such as the carbon % of a conformal SiOC films formed using the methods disclosed herein can be tuned to a desired range, such as in a range between about 0% and about 70% carbon content, such as between about 10% and about 60% carbon content, between about 20% and about 45%, or between about 30% and about 50% carbon content. As shown in FIG. 4, varying the processing conditions provided for forming SiOC dielectric films with varying atomic percentages of carbon content. As increased carbon content in dielectric films generally correlates with decreased dielectric constant of SiOC films, tuning of the chemical composition or carbon content of the deposited films in turn provides for also tuning the electrical property of the dielectric film so as to form low-k dielectric films. In an embodiment, the method of the present disclosure provides for tuning the dielectric constant of the as deposited film to between about 2 and about 5.

The methods and apparatuses disclosed herein provide for forming low-k dielectric films using a single precursor, while also providing for fine-tuning the composition and properties of the dielectric film by adjusting processing parameters during formation of the radicals and/or deposition of the dielectric film. Use of remote low energy plasma to selectively cleave precursors can assist in preserving desired precursor structures in the resulting dielectric film. Other advantages of the radical CVD process disclosed herein also include avoiding substrate and/or underlayer damage due to the use of remote low energy plasma and improved ash resistance to improve process integration. In general, deposition process parameters and process times may be adjusted to tune the chemical composition, electrical properties (dielectric constant), and/or mechanical properties (e.g., hardness (H) and Young’s modulus (E)) of the deposited film. The reaction gas flow rate, precursor gas flow rate, radical generation RF power, processing pressure, radical density, and substrate temperature are examples of adjustable process parameters. The process parameters can be adjusted alone or in combination with the process time. Accordingly, by fine tuning the above-noted parameters during radical generation and/or film deposition, conformal dielectric films with tunable composition and properties may be formed with step coverage of at least about 95%.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, within a range includes every point or individual value between its end points even though not explicitly recited. Thus, every point or individual value may serve as its own lower or upper limit combined with any other point or individual value or any other lower or upper limit, to recite a range not explicitly recited.

All numerical values within the detailed description herein are modified by “about” the indicated value, and take into account experimental error and variations that would be expected by a person having ordinary skill in the art.

All documents described herein are incorporated by reference herein, including any priority documents and or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise whenever a composition, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa.

While the present disclosure has been described with respect to a number of embodiments and examples, those skilled in the art, having benefit of this disclosure, will appreciate that other embodiments can be devised which do not depart from the scope and spirit of the present disclosure.

What is claimed is:

1. A method for processing a substrate, comprising:
disposing a substrate in a processing region of a process chamber;
flowing a reaction gas into a remote plasma region of the process chamber, the remote plasma region separated from the processing region by a showerhead having a first plurality of channels and a second plurality of channels;
flowing a precursor gas into the processing region through the second plurality of channels in the showerhead;
generating an inductively coupled plasma in the remote plasma region using the reaction gas to form plasma radicals; and
exposing the precursor gas in the processing region to plasma radicals to form a dielectric film on the substrate with at least 95% step coverage, wherein the plasma radicals are introduced into the processing region via the first plurality of channels of the showerhead.

2. The method of claim 1, further comprising flowing plasma radicals into the processing region through the first plurality of channels while generating the inductively coupled plasma in the remote plasma region.

3. The method of claim 1, wherein the first plurality of channels suppresses flow of ions from the remote plasma region to the processing region.

4. The method of claim 1, wherein the reaction gas comprises H₂ NH₃ Ar, He, N₂ O₂ or mixtures thereof.

5. The method of claim 1, wherein the precursor gas comprises CH₄ C₂H₂ C₃H_{6,} silane (SiH₄), disilane (Si₂H₆), tetraalkyl orthosilicate gases (TEOS), or mixtures thereof.

6. The method of claim 1, wherein the dielectric film comprises SiOC, Si, SiN, SiO, SiOCN, SiON, Carbon, SiC, BN, or BCN.

7. The method of claim 1, wherein a flow rate of the reaction gas is in a range from about 50 sccm to about 5000 sccm.

8. The method of claim 1, wherein a flow rate of the precursor gas is in a range from about 5 sccm to about 1000 sccm.

9. The method of claim 1, wherein a processing temperature is between about 150°C and about 600°C.

10. The method of claim 1, wherein generating the inductively coupled plasma comprises applying a RF Power in a range between about 200 Watts and about 6000 Watts.

11. The method of claim 1, wherein a processing pressure is between about .1 Torr and about 12 Torr.

12. The method of claim 1, wherein the dielectric film comprises a thickness between about 1 nm and about 50 nm.

13. The method of claim 1, wherein the plasma radicals comprise at least one of hydrogen radicals, nitrogen radicals, NO radicals, NH radicals, hydroxyl radicals, argon radicals, helium radicals, and oxygen radicals.

14. A method for processing a substrate, comprising:
disposing a substrate in a processing region of a process chamber, the substrate comprising at least one feature formed thereon;
flowing a reaction gas into a remote plasma region of the process chamber, the remote plasma region separated from the processing region by a showerhead having a first plurality of channels and a second plurality of channels;
flowing a precursor gas into a processing region through the second plurality of channels in the showerhead;
generating a plasma in the remote plasma region using the reaction gas to form plasma radicals;
flowing plasma radical into the processing region through the first plurality of channels in the showerhead; and
exposing the precursor gas in the processing region to plasma radicals to form a dielectric film on the substrate and feature thereon with at least 95% step coverage.

15. The method of claim 14, wherein the at least one feature comprises a critical dimension between about 20 nm and about 2000 nm.

16. The method of claim 14, wherein the at least one feature comprises an aspect ratio ranging between about 1:1. and about 50:1.

17. The method of claim 14, wherein the reaction gas comprises H₂ NH₃ Ar, He, N₂ O₂ or mixtures thereof.

18. The method of claim 14, wherein the precursor gas comprises CH₄ C₂H₂ C₃H_{6,} silane (SiH₄), disilane (Si₂H₆), tetraalkyl orthosilicate gases (TEOS), or mixtures thereof.

19. A method for processing a substrate, comprising:
disposing a substrate having at least one feature formed thereon in a processing region of a process chamber, wherein the at least one feature comprises an aspect ratio ranging between about 1:1. and about 50:1.;
flowing a reaction gas into a remote plasma region of the process chamber;
flowing a precursor gas into a processing region of the process chamber;
generating a plasma in the remote plasma region using the reaction gas to form plasma radicals;
flowing plasma radicals into the processing region; and
exposing the precursor gas in the processing region to plasma radicals to form a conformal dielectric film on the substrate, wherein the conformal dielectric film is formed on the substrate with at least 95% step coverage over the at least one feature and the substrate.

20. The method of claim 16, wherein the reaction gas comprises H₂ NH₃ Ar, He, N₂ O₂ or mixtures thereof, and the precursor gas comprises CH₄ C₂H₂ C₃H_{6,} silane (SiH₄), disilane (Si₂H₆), tetraalkyl orthosilicate gases (TEOS), or mixtures thereof.
